(19) United States
(12) Patent Application Publication
(10) Pub. No.: US 2025/0275170 A1
(43) Pub. Date: Aug. 28, 2025

(54) NITRIDE SEMICONDUCTOR DEVICE

(71) Applicant: Panasonic Holdings Corporation, Osaka (JP)

(72) Inventors: Satoshi TAMURA, Osaka (JP); Naoki TORII, Osaka (JP); Masahiro OGAWA, Osaka (JP)

(21) Appl. No.: 19/206,678

(22) Filed: May 13, 2025

Related U.S. Application Data
(63) Continuation of application No. PCT/JP2023/036963, filed on Oct. 12, 2023.

(30) Foreign Application Priority Data
Nov. 30, 2022 (JP) 2022-191497

(51) Int. Cl. H10D 30/47; H10D 62/85

(52) U.S. Cl. CPC H10D 30/476; H10D 30/475; H10D 62/8503

(57) ABSTRACT

A nitride semiconductor device includes: a substrate; a first semiconductor layer of a first conductivity type disposed above the substrate; a second semiconductor layer disposed above the first semiconductor layer, having a bandgap larger than that of the first semiconductor layer, and undoped; a third semiconductor layer of a second conductivity type disposed above the second semiconductor layer; a fourth semiconductor layer including a channel, and at least partially disposed above the third semiconductor layer; a gate electrode disposed above the first semiconductor layer; a drain electrode disposed below the substrate; and an insulating layer disposed above the gate electrode. The insulating layer covers a bottom and a side wall of a groove provided in an edge termination area of the nitride semiconductor device and penetrating through the third semiconductor layer to reach the second semiconductor layer.

### CROSS REFERENCE TO RELATED APPLICATIONS

This is a continuation application of PCT International Application No. PCT/JP2023/036963 filed on Oct. 12, 2023, designating the United States of America, which is based on and claims priority of Japanese Patent Application No. 2022-191497 filed on Nov. 30, 2022. The entire disclosures of the above-identified applications, including the specifications, drawings and claims are incorporated herein by reference in their entirety.

### FIELD

The present disclosure relates to a nitride semiconductor device.

### BACKGROUND

Nitride semiconductors, represented by gallium nitride (GaN), are wide bandgap semiconductors, and have a higher dielectric breakdown electric field strength and a higher saturated drift velocity of electrons than conventional silicon (Si) semiconductors, gallium arsenide (GaAs) semiconductors, and the like. Hence, research and development of power transistors using nitride semiconductors which are advantageous for high voltage resistance and high output have been actively conducted.

For example, Patent Literature (PTL) 1 discloses a vertical field effect transistor (FET) that includes: a regrown layer disposed to cover an opening provided in a GaN-based multilayer; and a gate electrode disposed on the regrown layer along the regrown layer. A channel is formed by two-dimensional electron gas (2DEG) generated in the regrown layer. A silicon oxide film, a silicon nitride film, an aluminum oxide film, and the like are formed as insulating layers that are in contact with the semiconductor surface.

### CITATION LIST

### Patent Literature

PTL 1: International Publication No. WO2022/176455

### SUMMARY

### Technical Problem

The nitride semiconductor device disclosed in PTL 1 has a problem in that the device may not be turned on properly under specific device driving conditions, leading to a low operation reliability. There is also a problem in the off characteristics that leakage current increases in an off state.

In view of the above, the present disclosure provides a nitride semiconductor device that has a high operation reliability and improved off characteristics.

### Solution to Problem

A nitride semiconductor device according to one aspect of the present disclosure includes: a substrate; a first semiconductor layer of a first conductivity type that is disposed above the substrate; a second semiconductor layer that is disposed above the first semiconductor layer, has a bandgap larger than a bandgap of the first semiconductor layer, and is undoped; a third semiconductor layer of a second conductivity type that is disposed above the second semiconductor layer; a fourth semiconductor layer that includes a channel and is at least partially disposed above the third semiconductor layer; a gate electrode that is disposed above the first semiconductor layer; a source electrode that is spaced apart from the gate electrode; a drain electrode that is disposed below the substrate; and an insulating layer that is disposed above the gate electrode. The insulating layer covers a bottom and a side wall of a groove provided in an edge termination area of the nitride semiconductor device, the groove penetrating through the third semiconductor layer to reach the second semiconductor layer.

### Advantageous Effects

According to the present disclosure, it is possible to provide a nitride semiconductor device that has a high operation reliability and improved off characteristics.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a nitride semiconductor device according to Embodiment 1.

FIG. 2 is a plan view of the nitride semiconductor device according to Embodiment 1.

FIG. 3 is a cross-sectional view of an edge termination area of a nitride semiconductor device according to a comparative example.

FIG. 4 is a cross-sectional view of an edge termination area of the nitride semiconductor device according to Embodiment 1.

FIG. 5 illustrates a relationship between Al composition ratio and leakage current in the nitride semiconductor device according to Embodiment 1.

FIG. 6 is a cross-sectional view of a nitride semiconductor device according to Embodiment 2.

FIG. 7 is a cross-sectional view of a nitride semiconductor device according to Embodiment 3.

FIG. 8 is a cross-sectional view of a nitride semiconductor device according to Embodiment 4.

### DESCRIPTION OF EMBODIMENTS

### Underlying Knowledge Forming Basis of the Present Disclosure

The inventors have found that the following problems arise with the conventional nitride semiconductor devices described in the “Background” section.

An insulating layer is disposed between the gate electrode and the field plate in the transistor area of the nitride semiconductor device disclosed in PTL 1. In the edge termination area of the nitride semiconductor device, portions of the p type semiconductor layer and the n type semiconductor layer are removed, so that the side portion of the p-n junction interface is exposed. An insulating layer is disposed to cover the surface of the n type semiconductor layer and the side portion of the p-n junction interface that are exposed. The insulating layer in the transistor area and the insulating layer in the edge termination area are formed simultaneously. For example, a silicon nitride (SIN) film formed by plasma chemical vapor deposition (CVD) or a silicon oxide (SiO₂) film formed by spin coating are used for the insulating layers.

However, when a deposition method, such as plasma CVD, which damages the surface of the semiconductor layer is used, the exposed side portion of the p-n junction interface degrades. This results in a problem in the off characteristics in which leakage current increases in an off state.

On the other hand, spin coating is available as a deposition method that causes little damage to the semiconductor layer. The spin coating is used, for example, to form SiO₂ films. However, the SiO₂ films formed by the spin coating are highly amorphous, and easily generate unintended charge in the films. In the transistor area of a nitride semiconductor device, the presence of an insulating layer in which charge is generated between the field plate connected to the source electrode and the gate electrode makes it difficult to perform proper application of the gate potential. As a result, switching problems arise, such as the device not turning on properly depending on the device driving conditions.

As described above, in conventional nitride semiconductor devices, it is difficult to inhibit both an increase in leakage current and the switching problems. In view of the above, the present disclosure provides a nitride semiconductor device that has improved off characteristics that are achieved by inhibiting an increase in leakage current, and a high operation reliability that is achieved by inhibiting the switching problems.

Examples of the nitride semiconductor device according to the present disclosure will be described below.

A nitride semiconductor device according to a first aspect of the present disclosure includes: a substrate; a first semiconductor layer of a first conductivity type that is disposed above the substrate; a second semiconductor layer that is disposed above the first semiconductor layer, has a bandgap larger than a bandgap of the first semiconductor layer, and is undoped; a third semiconductor layer of a second conductivity type that is disposed above the second semiconductor layer; a fourth semiconductor layer that includes a channel and is at least partially disposed above the third semiconductor layer; a gate electrode that is disposed above the first semiconductor layer; a source electrode that is spaced apart from the gate electrode; a drain electrode that is disposed below the substrate; and an insulating layer that is disposed above the gate electrode. The insulating layer covers a bottom and a side wall of a groove provided in an edge termination area of the nitride semiconductor device, the groove penetrating through the third semiconductor layer to reach the second semiconductor layer.

With this, the bottom of the groove serves as the top surface of the undoped second semiconductor layer, and the side wall of the groove does not expose the p-n junction interface between the first semiconductor layer and the third semiconductor layer. This prevents the damages that occur in the formation of the insulating layer from entering the p-n junction interface. Therefore, the leakage current in an off state in the edge termination area can be inhibited, thus improving the off characteristics. In addition, since damages to the p-n junction interface is prevented, plasma chemical vapor deposition or the like can be used to form insulating layers. This allows the formation of insulating layers having high crystallinity, and inhibits the generation of charge in the films. Therefore, degradation of the switching characteristics can be inhibited and the operation reliability can be improved. In this way, according to the present disclosure, it is possible to achieve a nitride semiconductor device that has a high operation reliability and improved off characteristics.

Moreover, in the nitride semiconductor device according to a second aspect of the present disclosure, for example, in the nitride semiconductor device according to the first aspect, the second semiconductor layer includes AlGaN as a main component.

With this, for example, when the third semiconductor layer and the first semiconductor layer are GaN layers, a potential barrier can be formed using the bandgap difference between GaN and AlGaN to inhibit leakage current in an off state. Moreover, the difference in etching rates between GaN and AlGaN facilitates etching control in the formation of the groove. Since the second semiconductor layer can be left sufficiently thick, the leakage current in an off state can be further inhibited.

Moreover, in the nitride semiconductor device according to a third aspect of the present disclosure, for example, in the nitride semiconductor device according to the first aspect or the second aspect, the first semiconductor layer includes GaN as a main component, and a composition ratio of Al in the second semiconductor layer is at least 10%.

This further inhibits the leakage current.

Moreover, in the nitride semiconductor device according to a fourth aspect of the present disclosure, for example, in the nitride semiconductor device according to any one of the first aspect to the third aspect, the bottom of the groove is flush with an interface between the second semiconductor layer and the third semiconductor layer, or positioned below and in a vicinity of the interface.

With this, since the second semiconductor layer can be left sufficiently thick, the leakage current in an off state can be further inhibited.

Moreover, in the nitride semiconductor device according to a fifth aspect of the present disclosure, for example, in the nitride semiconductor device according to any one of the first aspect to the fourth aspect, further includes: a fifth semiconductor layer that is disposed between the first semiconductor layer and the second semiconductor layer, has a bandgap smaller than the bandgap of the second semiconductor layer, and is undoped. The gate electrode overlaps, in a plan view, a first opening that penetrates through the third semiconductor layer, the second semiconductor layer, and the fifth semiconductor layer to reach the first semiconductor layer.

With this, the two-dimensional electron gas generated in the vicinity of the heterointerface between the second semiconductor layer and the fifth semiconductor layer facilitates the spread of current in the lateral direction of the nitride semiconductor device. This allows a low resistance to be achieved in an on state.

Moreover, in the nitride semiconductor device according to a sixth aspect of the present disclosure, for example, in the nitride semiconductor device according to any one of the first aspect to the fifth aspect, the fourth semiconductor layer includes a plurality of semiconductor films that have different bandgaps, the channel is two-dimensional electron gas generated at an interface between adjacent ones of the plurality of semiconductor films, the gate electrode overlaps, in a plan view, a first opening that penetrates through the third semiconductor layer and the second semiconductor layer to reach the first semiconductor layer, and a portion of the fourth semiconductor layer is disposed along an inner surface of the first opening between the inner surface of the first opening and the gate electrode.

With this, it is possible to achieve a vertical nitride semiconductor device that has a high operation reliability and improved off characteristics.

Moreover, the nitride semiconductor device according to a seventh aspect of the present disclosure, for example, in the nitride semiconductor device according to the sixth aspect, includes: a sixth semiconductor layer of the second conductivity type that is disposed between the fourth semiconductor layer and the gate electrode.

With this, the potential at the conduction band edge of the channel portion can be raised and the threshold voltage can be increased. Therefore, for example, it is possible to achieve a normally-off FET.

Moreover, in the nitride semiconductor device according to an eighth aspect of the present disclosure, for example, in the nitride semiconductor device according to any one of the first aspect to the fifth aspect, the gate electrode overlaps, in a plan view, a first opening that penetrates through the fourth semiconductor layer, the third semiconductor layer, and the second semiconductor layer to reach the first semiconductor layer. The nitride semiconductor device further includes: a gate insulating layer that is disposed along an inner surface of the first opening between the inner surface of the first opening and the gate electrode.

With this, it is possible to achieve a nitride semiconductor device having a recessed MISFET structure in which the operation reliability is high and the off characteristics are improved.

Moreover, in the nitride semiconductor device according to a ninth aspect of the present disclosure, for example, in the nitride semiconductor device according to the first aspect, the insulating layer has a monolayer structure including SiN or a stacked structure including SiN.

With this, the use of highly crystalline SiN inhibits the degradation of the switching characteristics, leading to an increase in reliability of the nitride semiconductor device.

Embodiments will be specifically described below with reference to drawings.

Each of the embodiments described below shows a general or specific example. Numerical values, shapes, materials, structural elements, the arrangement and connection of the structural elements, steps, the order of the steps, and the like shown in the following embodiments are examples, and are not intended to limit the present disclosure. Among the structural elements in the following embodiments, structural elements which are not recited in the independent claims are described as optional structural elements.

The drawings are schematic views and are not exactly illustrated. Hence, for example, scales and the like are not necessarily the same in the drawings. In the drawings, substantially the same configurations are identified with the same reference signs, and repeated descriptions are omitted or simplified.

In the present description, terms such as parallel and orthogonal which indicate relationships between elements, terms such as rectangular and trapezoid which indicate the shapes of elements, and numerical ranges are expressions which not only indicate exact meanings, but also indicate substantially equivalent ranges such as a range including a several percent difference.

In the present description and the drawings, an x-axis, a y-axis, and a z-axis indicate three axes of a three-dimensional orthogonal coordinate system. When the shape of a substrate in plan view is a rectangle, the x-axis and the y-axis respectively extend in a direction parallel to a first side of the rectangle and in a direction parallel to a second side orthogonal to the first side. The z-axis extends in the direction of thickness of the substrate. In the present description, the “direction of thickness” of the substrate refers to a direction perpendicular to the main surface of the substrate. The direction of thickness is the same as the stacking direction of semiconductor layers, and is also referred to as a “longitudinal direction”. A direction parallel to the main surface of the substrate may be referred to as a “lateral direction”.

The side (the positive side of the z-axis) on which a gate electrode and a source electrode are disposed with respect to the substrate is regarded as being “above” or “upper side”, and the side (the negative side of the z-axis) on which a drain electrode is disposed with respect to the substrate is regarded as being “below” or a “lower side”.

In the present description, terms of “above” and “below” do not indicate an upward direction (vertically upward) and a downward direction (vertically downward) in absolute spatial recognition but are used as terms for defining a relative positional relationship based on a stacking order in a stacked structure. The terms of “above” and “below” are applied not only to a case where two structural elements are spaced with another structural element present between the two structural elements, but also to a case where two structural elements are closely arranged and in contact with each other.

In the present description, “in plan view” means that the main surface of the substrate of a nitride semiconductor device is viewed in a direction perpendicular to the main surface, that is, that the main surface of the substrate is viewed from the front.

In the present description, unless otherwise specified, ordinal numbers such as “first” and “second” do not mean the number or order of structural elements but are used to avoid confusion of similar structural elements and to distinguish between them.

In the present description, AlGaN indicates a ternary mixed crystal of AlₓGa₁₋ₓN (0<x<1). In the following description, multinary mixed crystals are abbreviated by the sequences of structural element symbols such as AlInN and GaInN. For example, AlₓGa_{1-x-y}In_{y}N (0<x<1, 0<y<1, and 0<x+y<1) which is an example of a nitride semiconductor is abbreviated as AlGaInN.

### Embodiment 1

### Outline

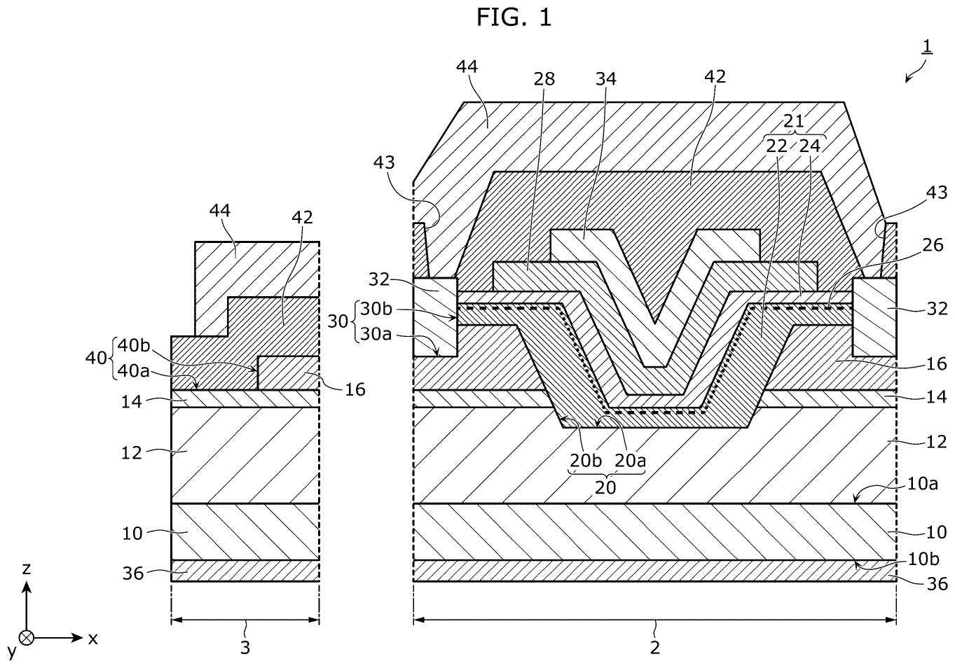

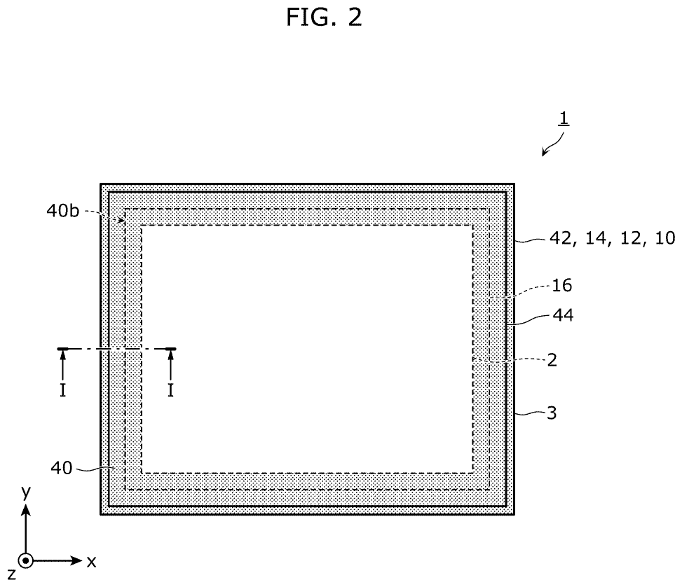

First, an outline of a nitride semiconductor device according to Embodiment 1 will be described with reference to FIG. 1 and FIG. 2.

FIG. 1 is a cross-sectional view of nitride semiconductor device 1 according to the present embodiment. FIG. 2 is a plan view of nitride semiconductor device 1 according to the present embodiment. FIG. 1 illustrates a cross-section taken along line I-I in FIG. 2. In FIG. 1, a portion between transistor area 2 and edge termination area 3 is schematically illustrated such that transistor area 2 and edge termination area 3 are separated.

As illustrated in FIG. 1, nitride semiconductor device 1 includes transistor area 2 and edge termination area 3. Specifically, nitride semiconductor device 1 includes substrate 10, drift layer 12, barrier layer 14, current blocking layer 16, gate opening 20, semiconductor multilayer film 21, threshold adjustment layer 28, source opening 30, source electrode 32, gate electrode 34, drain electrode 36, insulating layer 42, and source wiring 44. Semiconductor multilayer film 21 is a stack of electron transport layer 22 and electron supply layer 24, and includes two-dimensional electron gas (2DEG) 26 as a channel region. Nitride semiconductor device 1 also includes groove 40 provided in edge termination area 3.

Transistor area 2 is a region that includes a FET, and also includes the central portion of nitride semiconductor device 1, as illustrated in FIG. 2. Transistor area 2 serves as a current path between the source and the drain in an on state. Specifically, transistor area 2 is a region in which gate opening 20, semiconductor multilayer film 21, threshold adjustment layer 28, source electrode 32, and gate electrode 34 are disposed in plan view.

In FIG. 2, illustration of each structural element arranged in transistor area 2 is omitted. As an example, a plurality of source electrodes 32 elongated in one direction in plan view are arranged in stripes, and gate opening 20, semiconductor multilayer film 21, threshold adjustment layer 28, and gate electrode 34 are arranged between adjacent source electrodes. Alternatively, a plurality of source electrodes 32 that are hexagonal in plan view may be arranged to be spaced to fill a plane.

Edge termination area 3 is a region other than transistor area 2, and is provided in a ring shape to surround transistor area 2. Edge termination area 3 is a portion that does not serve as the current path between the source and the drain in an on state. Edge termination area 3 can be regarded as the region outside relative to the outermost periphery of source electrode 32. Gate opening 20, semiconductor multilayer film 21, threshold adjustment layer 28, source electrode 32, gate electrode 34, and the like are not disposed in edge termination area 3. Semiconductor multilayer film 21 and threshold adjustment layer 28 may be disposed in edge termination area 3 as long as semiconductor multilayer film 21 and threshold adjustment layer 28 are electrically separated from source electrode 32. In this case, too, groove 40 reaches barrier layer 14.

In the present embodiment, nitride semiconductor device 1 has a stacked structure of semiconductor layers that include, as a main component, nitride semiconductors, such as GaN and AlGaN. The phrase “A includes B as a main component” means that the content of B in A is at least 50%.

Specifically, nitride semiconductor device 1 has a heterostructure of AlGaN and GaN films. In the heterostructure of the AlGaN and GaN films, high-concentration two-dimensional electron gas 26 is generated at the heterointerface by spontaneous polarization or piezoelectric polarization on a (0001) plane. Hence, even in an undoped state, a sheet carrier concentration of at least 1×10¹³ cm⁻² can be obtained at the interface.

Nitride semiconductor device 1 according to the present embodiment is a field-effect transistor (FET) that uses, as a channel, two-dimensional electron gas 26 generated at the heterointerface of AlGaN/GaN. Specifically, nitride semiconductor device 1 is a so-called vertical FET.

Nitride semiconductor device 1 according to the present embodiment is a normally-off FET. Nitride semiconductor device 1 is turned on and off by adjustment of the potential applied to gate electrode 34. In nitride semiconductor device 1, for example, source electrode 32 is grounded (i.e., the potential is 0 V) and a positive potential is applied to drain electrode 36. Although the potential applied to drain electrode 36 is, for example, at least 100 V and at most 1200 V, the potential is not limited to such an example. When nitride semiconductor device 1 is in an off state, 0 V or a negative potential (e.g., −5 V) is applied to gate electrode 34. When nitride semiconductor device 1 is in an on state, a positive potential (e.g., +5 V) is applied to gate electrode 34. When nitride semiconductor device 1 is in an on state, current flows from drain electrode 36 to source electrode 32 via substrate 10, drift layer 12, and semiconductor multilayer film 21. Nitride semiconductor device 1 may be a normally-on FET.

### Configuration

Each structural element included in nitride semiconductor device 1 will be described below in detail.

Substrate 10 is a substrate of nitride semiconductors, and includes, as illustrated in FIG. 1, first main surface 10a and second main surface 10b that face away from each other. First main surface 10a is the main surface (top surface) on the side on which drift layer 12 is disposed. Specifically, first main surface 10a substantially coincides with a c-plane. Second main surface 10b is the main surface (bottom surface) on the side on which drain electrode 36 is disposed. Although the plan view shape of substrate 10 is, for example, a rectangle, the shape is not limited to the rectangle.

Substrate 10 is, for example, a substrate including n⁺ type GaN and having a thickness of 300 μm and a carrier concentration of 1×10¹⁸ cm⁻³. The n type and p type each indicate the conductivity type of a semiconductor. The n⁺ type indicates a state in which a high concentration of n type dopant is added into a semiconductor, that is, a so-called heavily doped state. The n⁻ type indicates a state in which a low concentration of n type dopant is added into a semiconductor, that is, a so-called lightly doped state. The same is true for the p⁺ type and p⁻ type. The n type, the n⁺ type and the n⁻ type are examples of a first conductivity type. The p type, the p⁺ type, and the p⁻ type are examples of a second conductivity type. The second conductivity type is the opposite polarity conductivity type of the first conductivity type.

Substrate 10 does not have to be a nitride semiconductor substrate. For example, substrate 10 may be a silicon (Si) substrate, silicon carbide (SiC) substrate, or zinc oxide (ZnO) substrate.

Drift layer 12 is an example of a first nitride semiconductor layer of the first conductivity type disposed above substrate 10. The conductivity type of drift layer 12 is identical to the conductivity type of substrate 10. Drift layer 12 includes GaN as a main component. The carrier concentration and thickness of drift layer 12 are important parameters that determine the voltage resistance of nitride semiconductor device 1, and are adjusted by the voltage for operating nitride semiconductor device 1. For example, when the rated voltage is 650 V, an n type GaN layer having a thickness of 8 μm and a carrier concentration of 1×10¹⁶ cm⁻³ is formed as drift layer 12. Si is generally used as an impurity that exhibits n type conductivity. The donor concentration of drift layer 12 is not limited to the above example, and may be, for example, in a range from at least 1×10¹⁵ cm⁻³ to at most 1×10¹⁷ cm⁻³. For example, the carbon concentration (C concentration) of drift layer 12 is in a range from at least 1×10¹⁵ cm⁻³ to at most 2×10¹⁷ cm⁻³.

Drift layer 12 is, for example, in contact with first main surface 10a of substrate 10. Drift layer 12 is formed on first main surface 10a of substrate 10 by crystal growth such as metal organic vapor phase epitaxy (MOVPE) or hydride vapor phase epitaxy (HVPE).

Barrier layer 14 is an example of a second nitride semiconductor layer that is disposed above drift layer 12, has a bandgap larger than the bandgap of drift layer 12, and is undoped. Barrier layer 14 includes AlGaN as a main component. The composition ratio (content) of Al in barrier layer 14 is at least 10%. Alternatively, the composition ratio of Al may be at least 15%. Barrier layer 14 is an undoped AlGaN layer having no intentional impurity doping.

Here, the term “undoped” means that GaN is not doped with a dopant, such as Si or Mg that changes the polarity of GaN to the n type or the p type. The term “undoped” may include cases where a very small amount of doping is performed to the extent that it does not contribute to conductivity.

Barrier layer 14 is in contact with the top surface of drift layer 12. Barrier layer 14 is formed on drift layer 12, for example, by crystal growth such as MOVPE or HVPE.

Barrier layer 14 is only required to have a bandgap larger than the material of drift layer 12. For example, barrier layer 14 may be a nitride semiconductor layer of quaternary mixed crystal such as AlGaInN.

Current blocking layer 16 is an example of a third nitride semiconductor layer of the second conductivity type disposed above barrier layer 14. Current blocking layer 16 is, for example, a layer including p type GaN. Current blocking layer 16, for example, has a thickness of 400 nm, and has a carrier concentration of 1×10¹⁷ cm⁻³. Current blocking layer 16 is in contact with the top surface of barrier layer 14. Current blocking layer 16 is formed on barrier layer 14, for example, by crystal growth, such as MOVPE or HVPE.

Mg can be used as an impurity that exhibits p type conductivity. Current blocking layer 16 may include a plurality of layers including at least a p type semiconductor layer. For example, current blocking layer 16 may include a p type GaN layer and a high-resistance semiconductor layer that is disposed on the p type GaN layer. The high-resistance semiconductor layer is a layer that has a resistance higher than the resistance of the p type GaN layer, and is, for example, a GaN layer doped with an element, such as carbon (C), which increases the resistance.

Current blocking layer 16 inhibits leakage current between source electrode 32 and drain electrode 36. For example, when a reverse voltage is applied to the p-n junction formed by current blocking layer 16 and drift layer 12, specifically, when the potential of drain electrode 36 is higher than the potential of source electrode 32, a depletion layer extends to drift layer 12. This allows nitride semiconductor device 1 to have a high voltage resistance. In the present embodiment, the potential of drain electrode 36 is higher than the potential of source electrode 32 both in an off state and in an on state, except in the case of a reverse conduction operation. Therefore, it is possible to increase the voltage resistance of nitride semiconductor device 1.

In the present embodiment, as illustrated in FIG. 1, current blocking layer 16 is in contact with source electrode 32. Therefore, current blocking layer 16 is fixed at the same potential as source electrode 32.

Gate opening 20 is an example of a first opening that penetrates through current blocking layer 16 and barrier layer 14 to reach drift layer 12. Bottom 20a of gate opening 20 is a portion of the top surface of drift layer 12. As illustrated in FIG. 1, bottom 20a is positioned below the bottom surface of barrier layer 14. The bottom surface of barrier layer 14 corresponds to the interface between barrier layer 14 and drift layer 12. Bottom 20a is parallel to, for example, first main surface 10a of substrate 10.

In the present embodiment, the opening area of gate opening 20 increases as the distance from substrate 10 increases. Specifically, each side wall 20b of gate opening 20 is inclined at an angle. As illustrated in FIG. 1, the cross-sectional shape of gate opening 20 is an inverted trapezoid, or more specifically, is an inverted isosceles trapezoid.

The angle of inclination of side wall 20b with respect to bottom 20a is, for example, in a range from at least 30° to at most 45°. With a decrease in the angle of inclination, the distance between side wall 20b and the c-plane decreases. This increases the film quality of electron transport layer 22 and the like formed along side wall 20b by crystal regrowth. On the other hand, with an increase in the angle of inclination, an excessive increase in the size of gate opening 20 is inhibited, leading to a reduction in size of nitride semiconductor device 1.

Gate opening 20 is formed by continuously forming, on first main surface 10a of substrate 10, drift layer 12, barrier layer 14, and current blocking layer 16 in this order and thereafter removing portions of current blocking layer 16 and barrier layer 14 such that drift layer 12 is partially exposed. Here, a surface layer portion of drift layer 12 is removed by a predetermined thickness, e.g., 300 nm, and thus, bottom 20a of gate opening 20 is formed below the bottom surface of barrier layer 14.

Current blocking layer 16 and barrier layer 14 are removed by, for example, dry etching, such as inductively coupled plasma (ICP) etching, in which chlorine gas is often used as the process gas. Current flows through gate opening 20 when nitride semiconductor device 1 is in an on state.

Semiconductor multilayer film 21 is an example of a fourth nitride semiconductor layer that includes a channel, and is at least partially disposed above current blocking layer 16. Specifically, semiconductor multilayer film 21 includes a plurality of semiconductor films that have different bandgaps. Two-dimensional electron gas 26 that is generated at the interface between adjacent ones of the semiconductor films serves as a channel. The term “channel” means at least a portion of the current path between the source and the drain.

In the present embodiment, a portion of semiconductor multilayer film 21 is disposed along the inner surface of gate opening 20 between the inner surface of gate opening 20 and gate electrode 34. Another portion of semiconductor multilayer film 21 is disposed above current blocking layer 16. Semiconductor multilayer film 21 is a stacked film of electron transport layer 22 and electron supply layer 24. Electron transport layer 22 and electron supply layer 24 are examples of a plurality of semiconductor films that have different bandgaps.

Electron transport layer 22 is an example of a first regrown layer disposed along the inner surface of gate opening 20. Specifically, a portion of electron transport layer 22 is disposed along bottom 20a and side walls 20b of gate opening 20, and the other portions of electron transport layer 22 are disposed on the top surface of current blocking layer 16. Electron transport layer 22 is, for example, a film including undoped GaN and having a thickness of 150 nm. Electron transport layer 22 may be not undoped, but doped with Si or the like to be n type electron transport layer 22.

Electron transport layer 22 is in contact with drift layer 12 at bottom 20a and side walls 20b of gate opening 20. Electron transport layer 22 is in contact with the end surfaces of barrier layer 14 and current blocking layer 16 at side walls 20b of gate opening 20. Electron transport layer 22 is also in contact with the top surface of current blocking layer 16. Electron transport layer 22 is formed by crystal regrowth after gate opening 20 is formed.

Electron transport layer 22 includes a channel region. Specifically, two-dimensional electron gas 26 is generated in the vicinity of the interface between electron transport layer 22 and electron supply layer 24. Two-dimensional electron gas 26 serves as a channel in electron transport layer 22. In FIG. 1, two-dimensional electron gas 26 is schematically illustrated by dashed lines. Two-dimensional electron gas 26 is bent along the interface between electron transport layer 22 and electron supply layer 24, i.e., along the inner surface of gate opening 20.

Moreover, although not illustrated in FIG. 1, an AlN film having a thickness of approximately 1 nm may be disposed as a second regrown layer between electron transport layer 22 and electron supply layer 24. The AlN film inhibits alloy scattering and increases the mobility of the channel.

Electron supply layer 24 is an example of a third regrown layer disposed along the inner surface of gate opening 20. Electron transport layer 22 and electron supply layer 24 are disposed in this order from the substrate 10 side. Electron supply layer 24 is formed along the top surface of electron transport layer 22 to have a substantially uniform thickness. Electron supply layer 24 is, for example, a film including undoped AlGaN and having a thickness of 50 nm. Electron supply layer 24 is formed by crystal regrowth, following the formation of electron transport layer 22.

Electron supply layer 24 has a bandgap larger than the bandgap of electron transport layer 22. Therefore, a heterointerface of AlGaN/GaN is formed between electron supply layer 24 and electron transport layer 22. This generates two-dimensional electron gas 26 in electron transport layer 22. Electron supply layer 24 supplies electrons to the channel region (i.e., two-dimensional electron gas 26) formed in electron transport layer 22.

At the heterointerface between AlGaN and GaN, high-concentration two-dimensional electron gas (2DEG) 26 is generated by spontaneous polarization or piezoelectric polarization on the (0001) plane. Two-dimensional electron gas 26 is a layer having a high electron mobility, and serves as a channel under the gate. Semiconductor multilayer film 21 is an n type semiconductor layer having a large number of electrons. The conductivity type of semiconductor multilayer film 21 is the same as the conductivity type of substrate 10 and drift layer 12.

Electron transport layer 22 and electron supply layer 24 are formed continuously by regrowth in MOVPE and HVPE and patterning after gate opening 20 is formed.

Threshold adjustment layer 28 is an example of a sixth semiconductor layer of the second conductivity type disposed between semiconductor multilayer film 21 and gate electrode 34. Specifically, threshold adjustment layer 28 is disposed between gate electrode 34 and electron supply layer 24. Threshold adjustment layer 28 is formed along the top surface of electron supply layer 24 to have a substantially uniform thickness.

Threshold adjustment layer 28 is, for example, a nitride semiconductor layer including p type GaN or AlGaN, and having a thickness of 100 nm and a carrier concentration of 1×10¹⁷ cm⁻³. In a similar manner to current blocking layer 16, Mg can be used as an impurity that exhibits p type conductivity. Threshold adjustment layer 28 is formed by regrowth in the MOVPE and HVPE and patterning, following the formation step of electron supply layer 24.

Threshold adjustment layer 28 is provided to raise the potential of the conduction band edge of the channel portion. Therefore, the threshold voltage of nitride semiconductor device 1 can be increased. Accordingly, nitride semiconductor device 1 can be implemented as a normally-off FET. In other words, nitride semiconductor device 1 can be turned off when a potential of 0 V is applied to gate electrode 34. Threshold adjustment layer 28 does not have to be disposed.

Source opening 30 is an example of a second opening that penetrates through semiconductor multilayer film 21 to reach current blocking layer 16 at a position distant from gate opening 20. Source opening 30 is positioned distant from gate electrode 34 in plan view.

Bottom 30a of source opening 30 serves as a portion of the top surface of current blocking layer 16. As illustrated in FIG. 1, bottom 30a is positioned below the bottom surface of semiconductor multilayer film 21. The bottom surface of semiconductor multilayer film 21 corresponds to the interface between semiconductor multilayer film 21 and current blocking layer 16. Bottom 30a is parallel to, for example, first main surface 10a of substrate 10.

As illustrated in FIG. 1, the opening area of source opening 30 is uniform regardless of the distance from substrate 10. Specifically, side wall 30b of source opening 30 is perpendicular to bottom 30a. In other words, the cross-sectional shape of source opening 30 is a rectangle.

Alternatively, in a similar manner to gate opening 20, the opening area of source opening 30 may increase as the distance from substrate 10 increases. Specifically, side wall 30b of source opening 30 may be inclined at an angle. For example, the cross-sectional shape of source opening 30 may be an inverted trapezoid, or more specifically, is an inverted isosceles trapezoid. Here, the angle of inclination of side wall 30b with respect to bottom 30a may be, for example, in a range from at least 30° to at most 60°. For example, the angle of inclination of side wall 30b of source opening 30 may be greater than the angle of inclination of side wall 20b of gate opening 20. Side wall 30b is inclined, and thus, the contact area between source electrode 32 and electron transport layer 22 (two-dimensional electron gas 26) is increased. This facilitates an ohmic connection. Two-dimensional electron gas 26 is exposed to side wall 30b of source opening 30, and is connected to source electrode 32 at the exposed portion.

Source electrode 32 is spaced apart from gate electrode 34. In the present embodiment, source electrode 32 is disposed along the inner surface of source opening 30. Specifically, source electrode 32 is connected to each of electron supply layer 24, electron transport layer 22, and current blocking layer 16. Source electrode 32 is ohmically connected to each of electron transport layer 22 and electron supply layer 24. Side wall 30b of source electrode 32 is in direct contact with two-dimensional electron gas 26. This reduces the contact resistance between source electrode 32 and two-dimensional electron gas 26 (channel).

Source electrode 32 is formed by using a conductive material, such as metal. Examples of the material of source electrode 32 include a material, such as Ti/Al, which is thermally processed to be ohmically connected to an n type GaN layer. Source electrode 32 is formed, for example, by patterning a conductive film formed by sputtering or electron-beam (EB) evaporation.

Gate electrode 34 is disposed above threshold adjustment layer 28, and overlaps gate opening 20 in plan view. Specifically, gate electrode 34 is in contact with the top surface of threshold adjustment layer 28 to cover gate opening 20. Gate electrode 34, for example, is formed along the top surface of threshold adjustment layer 28 to have a substantially uniform thickness. Alternatively, gate electrode 34 may be formed to fill a recess on the top surface of threshold adjustment layer 28.

Gate electrode 34 is formed by using a conductive material, such as metal. For example, gate electrode 34 is formed by using palladium (Pd). Examples of the material of gate electrode 34 include a material that is ohmically connected to a p type GaN layer, such as a nickel (Ni)-based material, tungsten silicide (WSi), or gold (Au). Gate electrode 34 is formed, after the formation of threshold adjustment layer 28, source opening 30, or source electrode 32, for example, by patterning a conductive film formed by sputtering, EB evaporation or the like.

Drain electrode 36 is disposed below substrate 10. Specifically, drain electrode 36 is disposed on the side opposite to drift layer 12. More specifically, drain electrode 36 is in contact with second main surface 10b of substrate 10. Drain electrode 36 is formed by using a conductive material, such as metal. Examples of the material of drain electrode 36 include, in a similar manner to the material of source electrode 32, a material, such as Ti/Al, which is ohmically connected to an n type GaN layer. Drain electrode 36 is formed, for example, by patterning a conductive film formed by sputtering, EB evaporation, or the like.

### Characteristic Configuration

Main characteristic configurations of nitride semiconductor device 1 according to the present embodiment will be described below. First, the details of each structural element in edge termination area 3 of nitride semiconductor device 1 will be described.

As illustrated in FIG. 1, in the present embodiment, semiconductor multilayer film 21 and threshold adjustment layer 28 are not disposed in edge termination area 3. For example, semiconductor multilayer film 21 and threshold adjustment layer 28 in edge termination area 3 are removed at the same time as the formation of source opening 30. A portion of current blocking layer 16 is also removed. In edge termination area 3, the top surface of current blocking layer 16 is positioned at the same height as bottom 30a of source opening 30. The phrase “at the same height” means that the distance from first main surface 10a of substrate 10 is the same. The same height is achieved because edge termination area 3 is simultaneously formed with source opening 30. When edge termination area 3 and source opening 30 are separately formed, the heights may be different.

Edge termination area 3 includes groove 40. Groove 40 is an isolation trench for partitioning and separating transistor area 2. Groove 40 penetrates through current blocking layer 16 to reach barrier layer 14.

Groove 40 includes bottom 40a and side wall 40b. In the present embodiment, groove 40 is a recessed portion that includes side wall 40b only on the transistor area 2 side. In other words, bottom 40a of groove 40 is connected to the end surface of nitride semiconductor device 1. Groove 40 is provided in the shape of a ring surrounding transistor area 2, as illustrated in FIG. 2.

Bottom 40a of groove 40 is a portion of the top surface of barrier layer 14. As illustrated in FIG. 1, bottom 40a is flush with the interface between barrier layer 14 and current blocking layer 16. Bottom 40a is parallel to, for example, first main surface 10a of substrate 10. Bottom 40a may be positioned below the interface between barrier layer 14 and current blocking layer 16.

Insulating layer 42 is disposed above gate electrode 34. Specifically, insulating layer 42 almost entirely covers transistor area 2, and includes an end portion that is positioned in edge termination area 3. Insulating layer 42 is disposed to cover bottom 40a and side wall 40b of groove 40. Insulating layer 42 includes contact hole 43 for exposing source electrode 32. Insulating layer 42 is in contact with and covers each of gate electrode 34, threshold adjustment layer 28, and electron supply layer 24. Insulating layer 42 is disposed so as not to expose the electrodes and semiconductor layers other than source electrode 32 exposed to contact hole 43.

Insulating layer 42 includes nitride as a main component. Insulating layer 42 is, for example, not a highly amorphous film formed by spin coating or the like, but, for example, is a silicon nitride film formed by plasma chemical vapor deposition. Specifically, insulating layer 42 has a monolayer structure of silicon nitride. Silicon nitride is highly crystalline, and is capable of inhibiting unintended generation of charge in the film. Therefore, it is possible to inhibit the phenomenon in which switching is not properly performed under specific driving conditions, which is one of the problems to be solved. Thus, the reliability of the operation of nitride semiconductor device 1 can be increased.

Source wiring 44 is disposed above insulating layer 42. In the present embodiment, source wiring 44 is in contact with and covers the top surface of insulating layer 42. Source wiring 44 penetrates through insulating layer 42 to be connected to source electrode 32. Specifically, source wiring 44 is disposed to fill contact hole 43 and electrically connects a plurality of source electrodes 32 to each other.

Source wiring 44 is formed by using a conductive material, such as metal. For example, the same material as source electrode 32 can be used for source wiring 44.

Source wiring 44 is also disposed in edge termination area 3. Specifically, source wiring 44 overlaps groove 40 in plan view. Source wiring 44 functions as a field plate when a source potential is applied to source wiring 44. Therefore, the electric field applied to the p-n junction interface in edge termination area 3 can be relaxed. Hence, it is possible to inhibit an increase in leakage current in an off state.

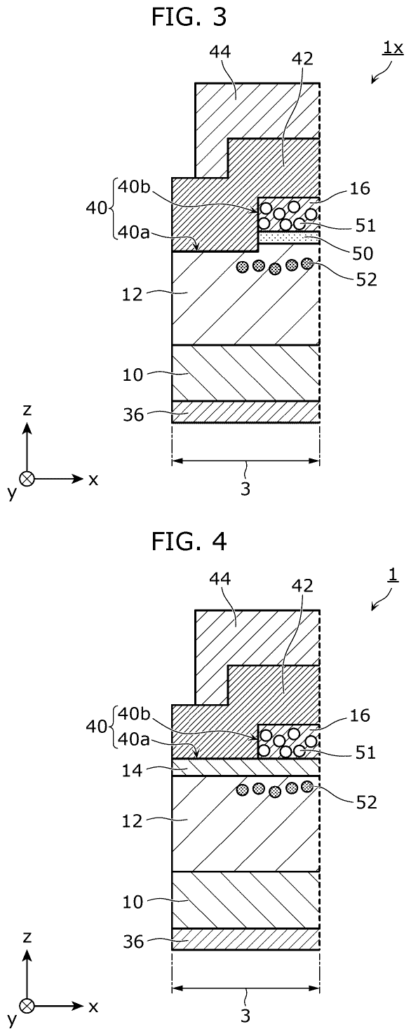

The functions of barrier layer 14 will be described below in comparison with the comparative example illustrated in FIG. 3.

FIG. 3 is a cross-sectional view of edge termination area 3 of nitride semiconductor device 1x according to a comparative example. As illustrated in FIG. 3, barrier layer 14 is not included in nitride semiconductor device 1x according to the comparative example. In other words, current blocking layer 16 of p type conductivity is in contact with drift layer 12 of n type conductivity. Groove 40 is formed by removing current blocking layer 16 until drift layer 12 is exposed. In other words, bottom 40a of groove 40 serves as the top surface of drift layer 12, and the interface between drift layer 12 and current blocking layer 16 is exposed to side wall 40b of groove 40. Insulating layer 42 is disposed to cover bottom 40a and side wall 40b.

At the interface between p type current blocking layer 16 and n type drift layer 12, depletion layer 50 is formed in which electrons 52 and holes 51 hardly exist. Therefore, the amount of leakage current that flows in an off state (specifically, state in which a positive voltage is applied to drain electrode 36 with respect to source wiring 44) is small. However, for example, when a silicon nitride film is formed as insulating layer 42 by the plasma chemical vapor deposition or the like in the portion of the p-n junction interface between p type current blocking layer 16 and n type drift layer 12 that is exposed to side wall 40b, a damage is caused at this time. The damage generates a trap that serves as a leak path in depletion layer 50 at the p-n junction portion. Such a trap causes a leak path along side wall 40b, which leads to an increase in leakage current in an off state.

In such a manner, when the junction interface between n type drift layer 12 and p type current blocking layer 16 is exposed to side wall 40b, the leakage current in an off state increases. In contrast, as illustrated in FIG. 4, in the present embodiment, barrier layer 14 is disposed between drift layer 12 and current blocking layer 16. FIG. 4 is a cross-sectional view of edge termination area 3 of nitride semiconductor device 1 according to the present embodiment.

Barrier layer 14 is an undoped AlGaN layer, and has a bandgap larger than the bandgap of drift layer 12. Barrier layer 14 includes a small number of electrons and holes supplied by impurities. Moreover, due to the potential barrier formed between barrier layer 14 and drift layer 12, the probability of electrons present in drift layer 12 being distributed in barrier layer 14 is also very small.

When the bandgap of barrier layer 14 is equivalent to the bandgap of drift layer 12, even when barrier layer 14 is in an undoped state, electrons are diffused from drift layer 12, so that barrier layer 14 can include a relatively large number of electrons.

Barrier layer 14 also serves as a stopper layer for etching when groove 40 is formed. In other words, the etching rate (speed) of barrier layer 14 is slower than the etching rate of current blocking layer 16. Therefore, after current blocking layer 16 is completely removed by etching, etching can easily be stopped at barrier layer 14. As a result, drift layer 12 is not exposed to bottom 40a of groove 40. The surface portion of barrier layer 14 may be removed by etching. In this case, bottom 40a of groove 40 is positioned below the interface between current blocking layer 16 and barrier layer 14.

When a silicon nitride film is formed as insulating layer 42 for such groove 40, by, for example, the plasma chemical vapor deposition, even when traps are generated at the exposed surface, the layer in which holes 51 are present is distant from the layer in which electrons 52 are present. Therefore, leak paths that cause an increase in leakage current are not generated. With the above effects, this configuration is capable of inhibiting an increase in leakage current in an off state which is one of the problems to be solved.

The larger the potential barrier formed between barrier layer 14 and drift layer 12, the harder it is for electrons in drift layer 12 to diffuse into barrier layer 14. In general, drift layer 12 often includes GaN. In such a case, the Al composition ratio of barrier layer 14 is, for example, at least 10%. Alternatively, the Al composition ratio of barrier layer 14 may be at least 15%.

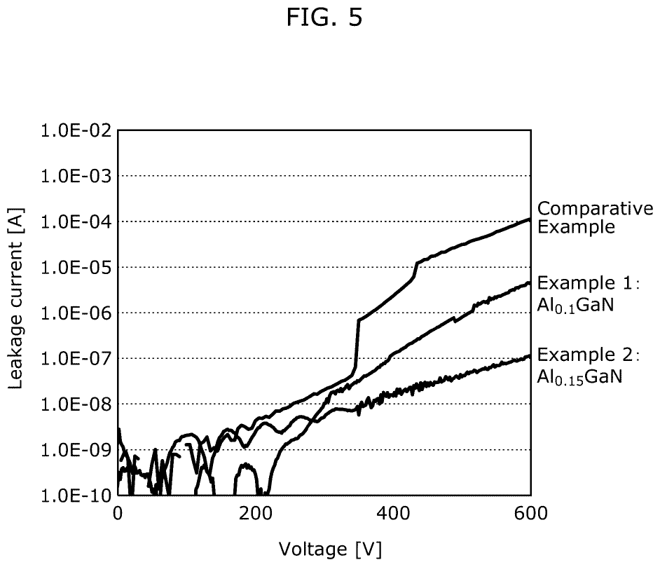

FIG. 5 illustrates a relationship between Al composition ratio and leakage current in nitride semiconductor device 1 according to the present embodiment. In FIG. 5, the horizontal axis represents voltage applied between the source and the drain. The vertical axis represents leakage current that flows between the source and the drain.

In FIG. 5, the comparative example represents the characteristics of nitride semiconductor device 1x having no barrier layer 14 as illustrated in FIG. 3. It can be understood that the leakage current increases as the voltage increases.

In contrast, Example 1 and Example 2 represent the characteristics of nitride semiconductor device 1. Barrier layer 14 in each of Example 1 and Example 2 is an AlGaN layer, and Example 1 and Example 2 are identical to each other in configuration except that the Al composition ratios are different from each other. Specifically, in Example 1, the Al composition ratio of barrier layer 14 is 10%. As is clear from FIG. 5, it is understood that the leakage current is inhibited due to the Al composition ratio of 10% in comparison with the comparative example. An increase in the Al composition ratio leads to an increase in the potential barrier. Therefore, by increasing the Al composition ratio of barrier layer 14 to, for example, at least 10%, an increase in leakage current can be further inhibited.

In Example 2, the Al composition ratio of barrier layer 14 is 15%. As is clear from FIG. 5, Example 2 in which the Al composition ratio is 15% is more effective in inhibiting the leakage current than in Example 1. Therefore, by increasing the Al composition ratio of barrier layer 14 to, for example, at least 15%, an increase in leakage current can be further inhibited. However, a significant increase in Al composition ratio leads to occurrence of cracks on barrier layer 14. Thus, for example, the Al composition ratio of barrier layer 14 may be at most 50%.

As described above, bottom 40a of groove 40 is flush with the interface between current blocking layer 16 and barrier layer 14, or is positioned below and in the vicinity of the interface. This increases the distance between the top surface of barrier layer 14 and drift layer 12 in which a large number of electrons are present, further inhibiting the leakage current in an off state.

The definition of “in the vicinity of the interface” will be described below. When removing current blocking layer 16 by etching, it is desirable to stop the etching just at the interface with barrier layer 14. However, due to the manufacturing method, the etching is actually stopped after slightly etching barrier layer 14. The region from the interface between current blocking layer 16 and barrier layer 14 to the top surface of barrier layer 14 exposed by slightly etching barrier layer 14 is defined as the region in the vicinity of the interface. The specific depth is within approximately 30 nm from the interface between current blocking layer 16 and barrier layer 14.

Barrier layer 14 includes Al. This has an advantage in the manufacturing method that after removing current blocking layer 16, which includes p type GaN, by dry etching, etching can be easily stopped at the interface between current blocking layer 16 and barrier layer 14. This is because the etching rate of the AlGaN layer is significantly lower than the etching rate of the GaN layer when dry etching is performed, for example, using oxygen-containing gas. This is effective for stopping the etching at and in the vicinity of the interface between current blocking layer 16 and barrier layer 14.

As described above, with nitride semiconductor device 1 according to the present embodiment, it is possible to inhibit the switching problem that occurs under the specific driving conditions of nitride semiconductor device 1, and also to inhibit an increase in leakage current generated when insulating layer 42 is formed in edge termination area 3. Therefore, according to the present embodiment, it is possible to achieve vertical nitride semiconductor device 1 that has a high operation reliability and improved off characteristics.

### Embodiment 2

Next, embodiment 2 will be described.

Embodiment 2 differs from Embodiment 1 in the peripheral structure of the gate electrode. Specifically, a nitride semiconductor device has a MISFET (insulated gate field effect transistor) structure having a gate insulating layer. The differences from Embodiment 1 will be mainly described below, and descriptions of shared features will be omitted or simplified.

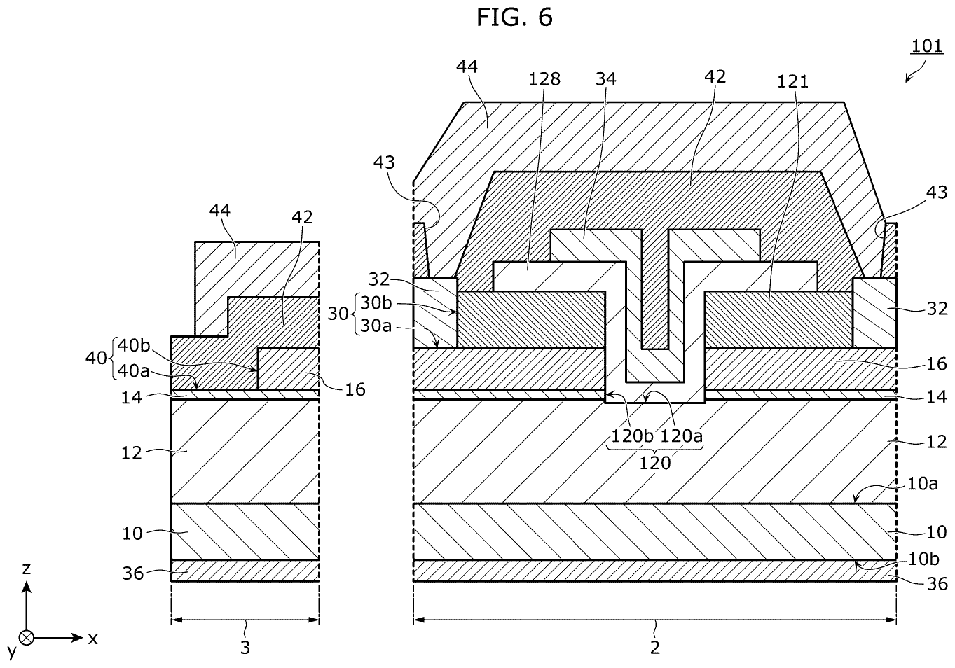

FIG. 6 is a cross-sectional view of nitride semiconductor device 101 according to the present embodiment.

As illustrated in FIG. 6, nitride semiconductor device 101 is different from nitride semiconductor device 1 illustrated in FIG. 1 in that gate opening 120, channel layer 121, and gate insulating layer 128 are included instead of gate opening 20, semiconductor multilayer film 21, and threshold adjustment layer 28.

Channel layer 121 is an example of a fourth nitride semiconductor layer that includes a channel and is at least partially disposed above current blocking layer 16. Specifically, channel layer 121 is in contact with and covers the top surface of current blocking layer 16. Channel layer 121 is, for example, an n type GaN layer. Channel layer 121 includes a large amount of n type impurities, and has a low resistance.

Channel layer 121 may include a plurality of semiconductor films that have different bandgaps, in a similar manner to Embodiment 1. Specifically, channel layer 121 may include an AlGaN layer and a GaN layer, and may include, as a channel, two-dimensional electron gas 26 generated in the vicinity of the heterointerface of AlGaN/GaN.

Channel layer 121 is formed continuously by crystal growth such as MOVPE, HVPE, or the like, following the formation of drift layer 12, barrier layer 14, and current blocking layer 16. Doping of impurities into channel layer 121 may be performed by ion implantation after crystal growth.

Gate opening 120 is an example of a first opening, and penetrates through channel layer 121. Specifically, gate opening 120 penetrates through channel layer 121, current blocking layer 16, and barrier layer 14 to reach drift layer 12. Bottom 120a of gate opening 120 serves as a portion of the top surface of drift layer 12.

As illustrated in FIG. 6, bottom 120a is positioned below the bottom surface of barrier layer 14. The bottom surface of barrier layer 14 corresponds to the interface between barrier layer 14 and drift layer 12. Bottom 120a is, for example, parallel to first main surface 10a of substrate 10.

As illustrated in FIG. 6, the opening area of gate opening 120 is uniform regardless of the distance from substrate 10. Specifically, each side wall 120b of gate opening 120 is perpendicular to bottom 120a. In other words, the cross-sectional shape of gate opening 120 is a rectangle.

Alternatively, in a similar manner to gate opening 20 in Embodiment 1, the opening area of gate opening 120 may increase as the distance from substrate 10 increases. Specifically, side wall 120b of gate opening 120 may be inclined at an angle. For example, the cross-sectional shape of gate opening 120 may be an inverted trapezoid, or more specifically, is an inverted isosceles trapezoid.

Gate insulating layer 128 is disposed along the inner surface of gate opening 120 between the inner surface of gate opening 120 and gate electrode 34. Specifically, gate insulating layer 128 and gate electrode 34 are disposed in this order along the inner surface of gate opening 120. More specifically, a portion of gate insulating layer 128 is disposed along bottom 120a and side wall 120b of gate opening 120. The other portions of gate insulating layer 128 are disposed over the top surface of channel layer 121. Gate insulating layer 128 is in contact with the end surface of each of barrier layer 14, current blocking layer 16, and channel layer 121 at side wall 120b of gate opening 120.

Gate insulating layer 128 is, for example, an insulating oxide film, such as a silicon nitride film, a silicon oxide film, or an aluminum oxide film. Gate insulating layer 128 may have a monolayer structure or a stacked structure.

In the present embodiment, after the continuous formation from drift layer 12 to channel layer 121, gate opening 120 is formed. In other words, unlike Embodiment 1, crystal regrowth is not performed. Instead of the crystal regrowth, gate insulating layer 128 is formed after gate opening 120 is formed. Gate insulating layer 128 is formed by, for example, plasma CVD, ALD, or sputtering.

In nitride semiconductor device 101 according to the present embodiment, by applying a positive voltage to gate electrode 34, an inverted channel is formed in current blocking layer 16, at the interface with gate insulating layer 128. This allows channel layer 121 and drift layer 12 to be electrically connected, turning on nitride semiconductor device 101. In an on state, current flows from drain electrode 36 to source electrode 32 via substrate 10, drift layer 12, the interface portion between current blocking layer 16 and gate insulating layer 128, and channel layer 121.

In the present embodiment, as insulating layer 42 disposed between gate electrode 34 and source wiring 44, in a similar manner to Embodiment 1, a silicon nitride film formed by, for example, plasma chemical vapor deposition can be used instead of a highly amorphous film formed by spin coating or the like. This inhibits the switching problems that occur under specific drive conditions. Moreover, edge termination area 3 includes a configuration identical to that in Embodiment 1. Hence, an increase in leakage current can be inhibited even when a silicon nitride film formed by plasma chemical vapor deposition or the like is formed as insulating layer 42.

As described above, nitride semiconductor device 101 according to the present embodiment inhibits the switching problems that occur under specific driving conditions, and also inhibits an increase in leakage current generated when insulating layer 42 is formed in edge termination area 3. Therefore, according to the present embodiment, it is possible to achieve vertical nitride semiconductor device 101 that has a high operation reliability and improved off characteristics.

### Embodiment 3

Next, Embodiment 3 will be described.

Embodiment 3 differs from Embodiment 1 in that an undoped semiconductor layer is disposed between the barrier layer and the drift layer in Embodiment 3. The differences from Embodiment 1 will be mainly described below, and the descriptions of shared features will be omitted or simplified.

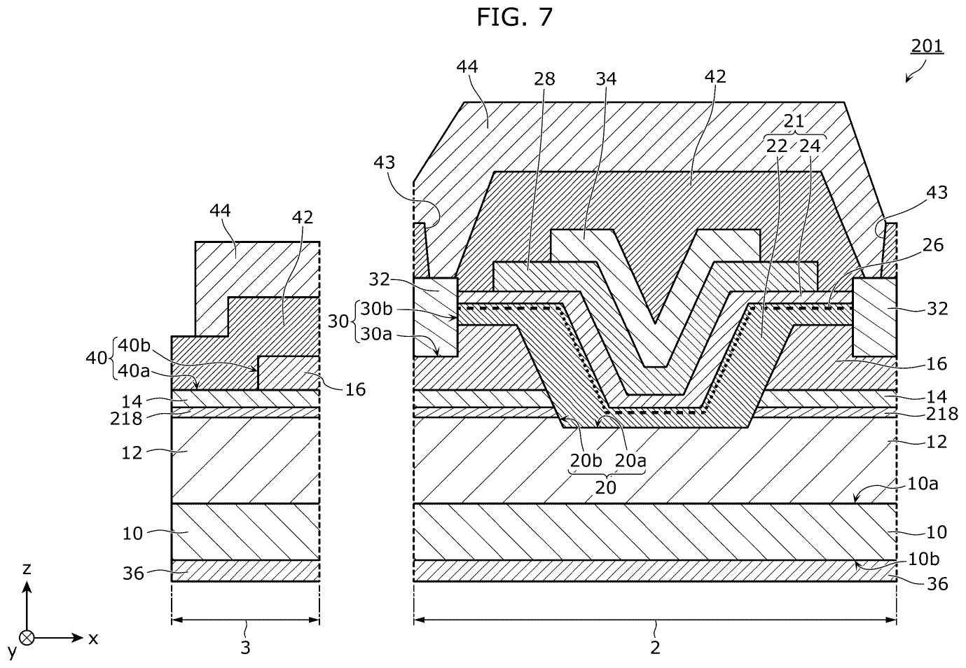

FIG. 7 is a cross-sectional view of nitride semiconductor device 201 according to the present embodiment. As illustrated in FIG. 7, nitride semiconductor device 201 differs from nitride semiconductor device 1 illustrated in FIG. 1 in that current diffusion layer 218 is additionally included.

Current diffusion layer 218 is an example of a fifth nitride semiconductor layer that is disposed between drift layer 12 and barrier layer 14, is undoped, and has a bandgap that is smaller than the bandgap of barrier layer 14. In the present embodiment, gate opening 20 penetrates through current blocking layer 16, barrier layer 14, and current diffusion layer 218.

Current diffusion layer 218 is, for example, an undoped GaN layer. Barrier layer 14 and current diffusion layer 218 form a heterointerface, and two-dimensional electron gas (2DEG) having a high mobility is formed in the vicinity of the heterointerface within current diffusion layer 218. The two-dimensional electron gas makes it easier for the current to spread laterally, thus reducing the resistance when the current flowing from drain electrode 36 to gate opening 20. This reduces the resistance of nitride semiconductor device 201 in an on state.

In the present embodiment, insulating layer 42 disposed between gate electrode 34 and source wiring 44 in transistor area 2 and edge termination area 3 are identical in configuration to those in Embodiment 1. Therefore, in a similar manner to Embodiment 1, it is possible to inhibit the switching problems that occur under specific driving conditions of nitride semiconductor device 201, and also inhibit an increase in leakage current generated when insulating layer 42 is formed in edge termination area 3. Therefore, according to the present embodiment, it is possible to achieve vertical nitride semiconductor device 201 that has a high operation reliability and improved off characteristics.

Current diffusion layer 218 may be included in nitride semiconductor device 101 having the MISFET structure described in Embodiment 2. In this case, too, as described above, it is possible to achieve a low resistance in an on state.

### Embodiment 4

Next, Embodiment 4 will be described.

Embodiment 4 differs from Embodiment 1 in that the insulating layer has a stacked structure. The differences from Embodiment 1 will be mainly described below, and the descriptions of shared features will be omitted or simplified.

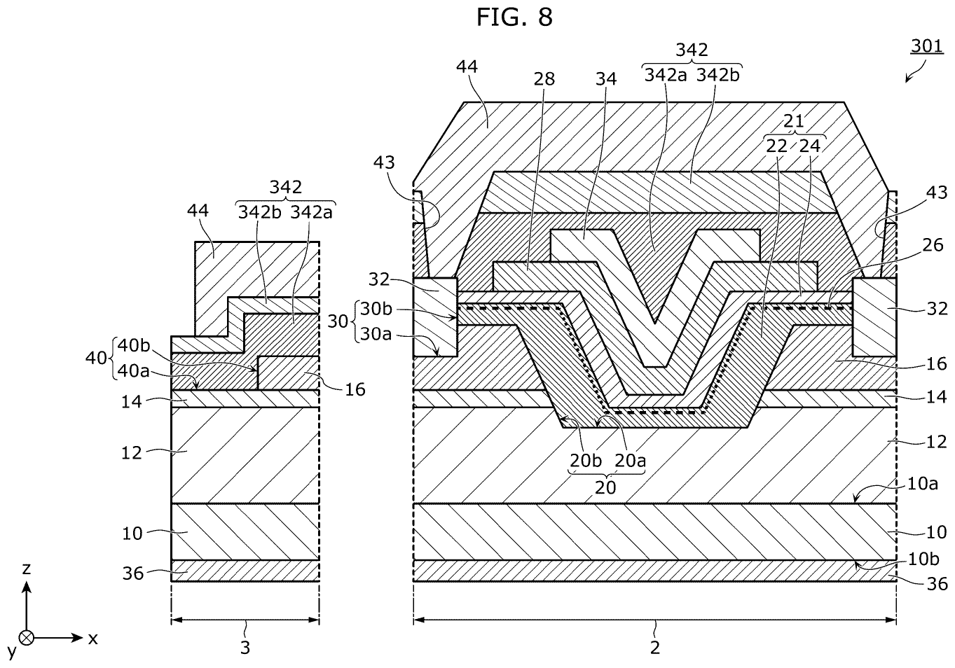

FIG. 8 is a cross-sectional view of nitride semiconductor device 301 according to the present embodiment. As illustrated in FIG. 8, nitride semiconductor device 301 differs from nitride semiconductor device 1 illustrated in FIG. 1 in that insulating layer 342 is included instead of insulating layer 42.

Insulating layer 342 has a stacked structure selected from, for example, the group consisting of SiN, SiO₂, HfO₂, Al₂O₃, ZrO₂, AlN, HfON and ZrON. Specifically, as illustrated in FIG. 8, insulating layer 342 includes lower insulating layer 342a and upper insulating layer 342b. Here, although FIG. 8 illustrates the stacked structure of two layers of insulating layers, it may be a stacked structure of three or more layers of insulating layers.

Lower insulating layer 342a is a lowermost insulating layer. Lower insulating layer 342a is in contact with gate electrode 34, threshold adjustment layer 28, and electron supply layer 24. Lower insulating layer 342a is SiN. Lower insulating layer 342a is formed, for example, by plasma chemical vapor deposition or sputtering.

Upper insulating layer 342b is, for example, a SiO₂ film formed by spin coating. Alternatively, upper layer insulating layer 342b may be a film including Al₂O₃ formed by the ALD. Upper insulating layer 342b may be an insulating layer formed by plasma chemical vapor deposition.

In this way, by providing highly crystalline SiN formed by plasma chemical vapor deposition or the like as lowermost lower insulating layer 342a, it is possible to inhibit one of the problems to be solved, namely, the phenomenon in which switching is not properly performed under the specific drive conditions. In addition, the stacked structure of insulating layer 342 allows the optimal film to be selected for each insulating layer, thereby further increasing the reliability of the device.

Insulating layer 342 having a stacked structure may be disposed in nitride semiconductor devices 101 and 201 according to Embodiments 2 and 3.

### Other Embodiments

The nitride semiconductor devices according to one or more aspects have been described based on the embodiments. However, the present disclosure is not limited to these embodiments. Embodiments obtained by performing, on the embodiments, various variations conceived by a person skilled in the art and embodiments established by combining structural elements in different embodiments are also included in the scope of the present disclosure as long as they do not depart from the spirit of the present disclosure.

For example, source opening 30 does not have to be disposed. In this case, source electrode 32 is disposed on the top surface of semiconductor multilayer film 21, at a position distant from threshold adjustment layer 28. The process of forming source opening 30 can be omitted, thereby simplifying the manufacturing process.

Insulating layer 42 or 342 in transistor area 2 may have different configurations from insulating layer 42 or 342 in edge termination area 3. For example, different materials may be used for forming the insulating layer covering gate electrode 34 in transistor area 2 and the insulating layer covering groove 40 in edge termination area 3. Alternatively, the insulating layer covering gate electrode 34 may have a stacked structure, while the insulating layer covering groove 40 may have a monolayer structure. On the other hand, the insulating layer covering gate electrode 34 may have a monolayer structure, while the insulating layer covering groove 40 may have a stacked structure.

Moreover, for example, drift layer 12 may have a graded structure in which the impurity concentration (donor concentration) is gradually reduced from the substrate 10 side to the barrier layer 14 side. The donor concentration may be controlled by Si that serves as a donor or by carbon that serves as an acceptor for compensating for Si. Alternatively, drift layer 12 may have a stacked structure of a plurality of nitride semiconductor layers having different impurity concentrations.

Moreover, for example, edge termination area 3 does not have to include the end surface of nitride semiconductor device 1. Edge termination area 3 is a portion for separating transistor area 2 from other devices. Other elements may be disposed in a region adjacent to transistor area 2 through edge termination area 3.

The first conductivity type may be p type, p⁺ type, or p⁻ type, and the second conductivity type may be n type, n⁺ type, or n⁻ type.

In the embodiments described above, various changes, replacements, additions, omissions, and the like can be performed without departing from the scope of claims or the scope equivalent thereto.

### INDUSTRIAL APPLICABILITY

The present disclosure can be used as a nitride semiconductor device in which off characteristics and switching characteristics are improved, and can be used, for example, as a power device, such as a power transistor used in an inverter circuit, a power supply circuit and the like of a consumer device such as a television, an in-vehicle device, and an industrial apparatus.

1. A nitride semiconductor device comprising:
a substrate;
a first semiconductor layer of a first conductivity type that is disposed above the substrate;
a second semiconductor layer that is disposed above the first semiconductor layer, has a bandgap larger than a bandgap of the first semiconductor layer, and is undoped;
a third semiconductor layer of a second conductivity type that is disposed above the second semiconductor layer;
a fourth semiconductor layer that includes a channel and is at least partially disposed above the third semiconductor layer;
a gate electrode that is disposed above the first semiconductor layer;
a source electrode that is spaced apart from the gate electrode;
a drain electrode that is disposed below the substrate; and
an insulating layer that is disposed above the gate electrode,
wherein the insulating layer covers a bottom and a side wall of a groove provided in an edge termination area of the nitride semiconductor device, the groove penetrating through the third semiconductor layer to reach the second semiconductor layer.

2. The nitride semiconductor device according to claim 1,
wherein the second semiconductor layer includes AlGaN as a main component.

3. The nitride semiconductor device according to claim 2,
wherein the first semiconductor layer includes GaN as a main component, and
a composition ratio of Al in the second semiconductor layer is at least 10%.

4. The nitride semiconductor device according to claim 1,
wherein the bottom of the groove is flush with an interface between the second semiconductor layer and the third semiconductor layer, or positioned below and in a vicinity of the interface.

5. The nitride semiconductor device according to claim 1, further comprising:
a fifth semiconductor layer that is disposed between the first semiconductor layer and the second semiconductor layer, has a bandgap smaller than the bandgap of the second semiconductor layer, and is undoped,
wherein the gate electrode overlaps, in a plan view, a first opening that penetrates through the third semiconductor layer, the second semiconductor layer, and the fifth semiconductor layer to reach the first semiconductor layer.

6. The nitride semiconductor device according to claim 1,
wherein the fourth semiconductor layer includes a plurality of semiconductor films that have different bandgaps,
the channel is two-dimensional electron gas generated at an interface between adjacent ones of the plurality of semiconductor films,
the gate electrode overlaps, in a plan view, a first opening that penetrates through the third semiconductor layer and the second semiconductor layer to reach the first semiconductor layer, and
a portion of the fourth semiconductor layer is disposed along an inner surface of the first opening between the inner surface of the first opening and the gate electrode.

7. The nitride semiconductor device according to claim 6, comprising:
a sixth semiconductor layer of the second conductivity type that is disposed between the fourth semiconductor layer and the gate electrode.

8. The nitride semiconductor device according to claim 1,
wherein the gate electrode overlaps, in a plan view, a first opening that penetrates through the fourth semiconductor layer, the third semiconductor layer, and the second semiconductor layer to reach the first semiconductor layer,
the nitride semiconductor device further comprises:
a gate insulating layer that is disposed along an inner surface of the first opening between the inner surface of the first opening and the gate electrode.

9. The nitride semiconductor device according to claim 1,
wherein the insulating layer has a monolayer structure including SiN or a stacked structure including SiN.
